(19) United States
(12) Patent Application Publication
(10) Pub. No.: US 2025/0019227 A1
(43) Pub. Date: Jan. 16, 2025

(54) MEMS DEVICE AND ELECTRONIC DEVICE

(71) Applicants: Beijing BOE Technology Development Co., Ltd., Beijing (CN); BOE Technology Group Co., Ltd., Beijing (CN)

(72) Inventor: Yingli SHI, Beijing (CN)

(21) Appl. No.: 18/711,946

(22) PCT Filed: Oct. 24, 2022
(86) PCT No.: PCT/CN2022/127098

§ 371 Date: May 21, 2024

(51) Int. Cl. B81B 3/00

(52) U.S. Cl. CPC B81B 3/007; B81B 2203/0109; B81B 2203/04

(57) ABSTRACT

The embodiments of the present disclosure provide an MEMS device and an electronic device. The MEMS device includes: a base substrate; an electrode structure, which is located on the base substrate and includes a first ground electrode, a signal transmission electrode and a second ground electrode, which are sequentially arranged on the base substrate at intervals; a metal film bridge, which spans above the signal transmission electrode and forms a cavity with the signal transmission electrode, where two ends of the metal film bridge are respectively electrically connected to the first ground electrode and the second ground electrode; and a support structure, which is fixedly arranged with the metal film bridge, wherein the Young's modulus of the support structure is greater than the Young's modulus of the metal film bridge.

### CROSS REFERENCE TO RELATED APPLICATIONS

The present disclosure is a national phase entry under 35 U.S.C § 371 of International Application No. PCT/CN2022/127098, filed Oct. 24, 2022, the entire content of which is incorporated herein by reference.

### TECHNICAL FIELD

The present disclosure relates to the technical field of MEMS device, and in particular to an MEMS device and an electronic device.

### BACKGROUND

The radio frequency (RF) switch designed and fabricated by Micro-Electro-Mechanical Systems (MEMS) technology has the unique advantages of low insertion loss and low electrical power consumption. The RF switch is one of the most basic components of electronic circuit systems such as wireless communication, which is widely used in radar detection, wireless communication, etc. The new generation of information technology with miniaturization and high function density as its development direction calls for a new generation of high-performance components. Compared with switches composed of traditional Field Effect Transistors (FET) or (Positive-Intrinsic-Negative) PIN diodes, RF MEMS switch has the advantages of low insertion loss, low electrical power consumption and low distortion of transmission signal.

### SUMMARY

Embodiments of the present disclosure provide an MEMS device and an electronic device, and the specific schemes are as follows.

Embodiments of the present disclosure provide an MEMS device, including:
a base substrate;
an electrode structure on the base substrate, where the electrode structure includes a first ground electrode, a signal transmission electrode, and a second ground electrode arranged in sequence and spaced on the base substrate;
a metal film bridge spanning above the signal transmission electrode and forming a cavity with the signal transmission electrode, where two ends of the metal film bridge are electrically connected with the first ground electrode and the second ground electrode, respectively; and
a support structure, fixedly arranged with the metal film bridge, where a Young's modulus of the support structure is greater than a Young's modulus of the metal film bridge.

In a possible implementation, in the above MEMS device provided by the embodiments of the present disclosure, the support structure includes a first support layer, the first support layer is arranged on a side of the metal film bridge facing the base substrate; an orthographic projection of the signal transmission electrode on the base substrate and
an orthographic projection of the metal film bridge on the base substrate have an overlapping area; and
an orthographic projection of the first support layer on the base substrate at least completely covers an orthographic projection of the overlapping area on the base substrate.

In a possible implementation, in the above MEMS device provided by the embodiments of the present disclosure, the orthographic projection of the first support layer on the base substrate completely covers an orthographic projection of a bottom surface of the metal film bridge on the base substrate, where the bottom surface of the metal film bridge is a surface of the metal film bridge facing the base substrate.

In a possible implementation, in the above MEMS device provided by the embodiments of the present disclosure, the first support layer includes a first sub support layer; and an orthographic projection of the first sub support layer on the base substrate completely covers the orthographic projection of the overlapping area on the base substrate.

In a possible implementation, in the above MEMS device provided by the embodiments of the present disclosure, the first support layer further includes a second sub support layer and a third sub support layer;
the first sub support layer, the second sub support layer and the third sub support layer are on a same layer and arranged independently of each other; and
the second sub support layer and the third sub support layer are located on both sides of the first sub support layer, respectively.

In a possible implementation, in the above MEMS device provided by the embodiments of the present disclosure, the second sub support layer and the third sub support layer are symmetrically arranged with respect to a central position of the first sub support layer.

In a possible implementation, in the above MEMS device provided by the embodiments of the present disclosure, the support structure further includes a second support layer; and the second support layer is arranged on a side of the metal film bridge facing away from the base substrate.

In a possible implementation, in the above MEMS device provided by the embodiments of the present disclosure, the support structure includes a second support layer; and the second support layer is arranged on a side of the metal film bridge facing away from the base substrate; the MEMS device further includes a dielectric layer on a side of the signal transmission electrode facing away from the base substrate; an orthographic projection of the signal transmission electrode on the base substrate and an orthographic projection of the metal film bridge on the base substrate have an overlapping area; and an orthographic projection of the overlapping area on the base substrate is located within an orthographic projection of the dielectric layer on the base substrate.

In a possible implementation, in the above MEMS device provided by the embodiments of the present disclosure, an orthographic projection of the second support layer on the base substrate completely covers an orthographic projection of a top surface of the metal film bridge on the base substrate, where the top surface of the metal film bridge is a surface of the metal film bridge facing away from the base substrate.

In a possible implementation, in the above MEMS device provided by the embodiments of the present disclosure, the second support layer includes at least two fourth sub support layers independently arranged with each other.

In a possible implementation, in the above MEMS device provided by the embodiments of the present disclosure, the at least two fourth sub support layers is uniformly distributed.

In a possible implementation, in the above MEMS device provided by the embodiments of the present disclosure, a shape of the metal film bridge is an arch protruding toward a side away from the base substrate.

In a possible implementation, in the above MEMS device provided by the embodiments of the present disclosure, a material of the metal film bridge includes Au, Ag, Cu or Al; and a material of the support structure includes SiNx or SiO₂.

In a possible implementation, in the above MEMS device provided by the embodiments of the present disclosure, a thickness of the support structure ranges from 100 nm to 200 nm.

Accordingly, the embodiments of the present disclosure further provide an electronic device, including the above MEMS device provided by embodiments of the present disclosure.

### BRIEF DESCRIPTION OF FIGURES

FIG. 1 is a schematic structural diagram of an MEMS device in the up state provided in the related art.

FIG. 2 is a schematic structural diagram of an MEMS device in the down state provided in the related art.

FIGS. 3 to 18 are schematic structural diagrams of MEMS devices provided by embodiments of the present disclosure.

### DETAILED DESCRIPTION

In order to make the purpose, technical solutions and advantages of embodiments of the present disclosure more clear, the technical solutions of embodiments of the present disclosure will be clearly and completely described below in conjunction with the drawings of embodiments of the present disclosure. Obviously, the described embodiments are some, but not all of the embodiments of the present disclosure. Moreover, embodiments and features in the embodiments of the present disclosure may be combined with each other without conflict. Based on the described embodiments of the present disclosure, all other embodiments obtained by those of ordinary skill in the art without creative efforts fall within the scope of the present disclosure.

Unless otherwise defined, technical terms or scientific terms used in this disclosure shall have the usual meaning understood by a person with ordinary skill in the art to which this disclosure belongs. Words such as “including” or “comprising” refer to the components or objects that appear before the word, including those listed after the word and their equivalents, without excluding other components or objects. Words such as “connected” or “connecting” are not limited to physical or mechanical connections, but may include electrical connections, whether direct or indirect. Words such as “inside”, “outside”, “up”, “down” are only used to express relative positional relationships. When the absolute position of the described object is changed, the relative positional relationship may also be changed accordingly.

It should be noted that the sizes and shapes of the figures in the drawings do not reflect true proportions and are only intended to illustrate the present disclosure. And, the same or similar reference numbers throughout represent the same or similar components or elements having the same or similar functions.

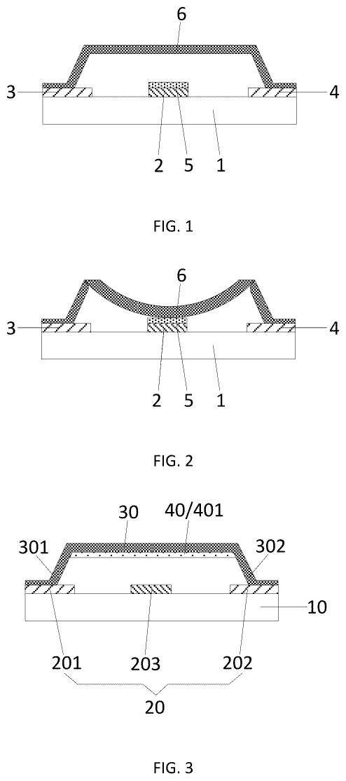

The common structures of MEMS devices include double end fixed beam film bridge structure and cantilever beam structure. Because the double end fixed beam film bridge structure has high elastic coefficient and simple preparation process, it is widely used in MEMS devices. The common structure of capacitive RF MEMS device is shown in FIG. 1, including: a base substrate 1, a signal transmission electrode 2, a first ground electrode 3, a second ground electrode 4, a dielectric layer 5, and a metal film bridge 6. The signal transmission electrode 2, the first ground electrode 3 and the second ground electrode 4 are arranged on the base substrate 1 and on the same side of the base substrate 1, and the first ground electrode 3 and the second ground electrode 4 are distributed on both sides of the signal transmission electrode 2. The dielectric layer 5 is located directly above the signal transmission electrode 2, and a width of the dielectric layer 5 should be greater than or equal to a width of the signal transmission electrode 2. The metal film bridge 6 is prepared above the first ground electrode 3 and the second ground electrode 4, and the metal film bridge 6 spans above the signal transmission electrode 2 and the dielectric layer 5. The deformation of metal film bridge 6 is controlled by applying DC bias voltage, and a controllable movement is realized under the combined action of electrostatic driving force and mechanical recovery force of metal film bridge 6. It can be divided into UP state and DOWN state before and after execution, corresponding to the on and off state of the switch. FIG. 1 shows the double end fixed beam film bridge structure of MEMS devices in the “UP” state, and FIG. 2 shows the double end fixed beam film bridge structure of MEMS devices in the “DOWN” state. The structure and process principle of MEMS devices shown in FIG. 1 are simple. Generally, the sacrificial layer process is used to fabricate the metal film bridge 6. However, the key of the fabricating process is the stress control of the film of the metal film bridge 6. Due to the residual stress and stress gradient of the film, the metal film bridge 6 may collapse or warp several microns, which may lead to the failure of MEMS device preparation.

In view of this, to prevent the metal film bridge from collapsing or warping and other failure problems in the preparation process, embodiments of the present disclosure provide an MEMS device, as shown in FIGS. 3 to 7, including:
a base substrate 10;
an electrode structure 20 on the base substrate 10, where the electrode structure 20 includes a first ground electrode 201, a signal transmission electrode 203, and a second ground electrode 202 arranged in sequence and spaced on the base substrate 10;
a metal film bridge 30 spanning above the signal transmission electrode 203 and forming a cavity with the signal transmission electrode 203, where two ends of the metal film bridge 30 are electrically connected with the first ground electrode 201 and the second ground electrode 202, respectively; and
a support structure 40, fixedly arranged with the metal film bridge 30, where a Young's modulus of the support structure 40 is greater than a Young's modulus of the metal film bridge 30.

In the above MEMS device provided by embodiments of the disclosure, the support structure fixed with the metal film bridge is arranged, since the Young's modulus of the support structure is greater than the Young's modulus of the metal film bridge, the support structure may provide strong support for the metal film bridge and enhance the bending stiffness of the metal film bridge, to prevent the metal film bridge from collapsing or warping and other failure problems during the preparation process, so that the MEMS device can maintain good structure, function and stability.

Specifically, as shown in FIGS. 3 to 7, when applying voltage to the metal film bridge 30 and the signal transmission electrode 203, the metal film bridge 30 is close to the signal transmission electrode 203. When no voltage is applied (i.e. no voltage is applied to the metal film bridge 30 and the signal transmission electrode 203), the metal film bridge 30 is far away from the signal transmission electrode 203, that is, the metal film bridge 30 is not close to the signal transmission electrode 203. Therefore, the MEMS device have the ability to bring the metal film bridge 30 close to the signal transmission electrode 203 when a certain voltage is applied, and to move the metal film bridge 30 far away from the signal transmission electrode 203 when no voltage is applied, to achieve functions similar to switching devices.

In specific implementation, in the above MEMS device provided by embodiments of the present disclosure, as shown in FIG. 3, the support structure 40 includes a first support layer 401, the first support layer 401 is arranged on a side of the metal film bridge 30 facing the base substrate 10; an orthographic projection of the signal transmission electrode 203 on the base substrate 10 and an orthographic projection of the metal film bridge 30 on the base substrate 10 have an overlapping area (that is, the area where the signal transmission electrode 203 is located); and an orthographic projection of the first support layer 401 on the base substrate 10 at least completely covers an orthographic projection of the overlapping area on the base substrate 10. In this way, the first support layer 401 not only plays the role of supporting the metal film bridge 30, but also can replace the dielectric layer 5 in FIG. 1 of the related art. The first support layer 401 acts as a DC bias voltage dielectric layer, which can eliminate the signal transmission loss caused by the dielectric layer 5 in FIG. 1, thereby reducing the insertion loss of MEMS devices.

In specific implementation, in order to ensure that the first support layer can provide strong support for all positions of the metal film bridge, in the above MEMS device provided by embodiments of the present disclosure, as shown in FIG. 3, the orthographic projection of the first support layer 401 on the base substrate 10 completely covers an orthographic projection of a bottom surface of the metal film bridge 30 on the base substrate 10, where the bottom surface of the metal film bridge is a surface of the metal film bridge facing the base substrate.

Compared with the structure of FIG. 1, the embodiment shown in FIG. 3 designs the MEMS device into a stacked structure of the first support layer 401 (equivalent to the dielectric layer)/metal film bridge 30. The inventor of the disclosure finds through finite element simulation that the structure shown in FIG. 3 can improve the support of the metal film bridge 30. Under the same external force, compared with the structure shown in FIG. 1 before improvement, the deformation of metal film bridge 30 can be reduced by 65% (that is, the collapse risk can be reduced by 65% compared with FIG. 1), and the support effect can be adjusted by changing the structural parameters and materials of the first support layer 401.

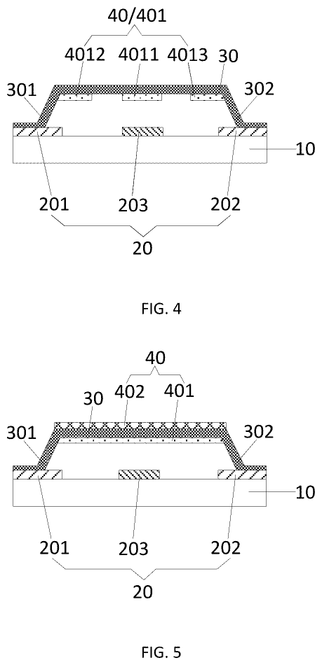

In specific implementation, the first support layer 401 in the structure shown in FIG. 3 can provide good support for the metal film bridge 30, but the design of the first support layer 401 makes the stiffness of the metal film bridge 30 larger. When the MEMS device needs to be in the off state (DOWN), a larger driving voltage needs to be applied, resulting in increased power consumption. Therefore, in order to reduce the power consumption of the MEMS device, in the above MEMS device provided by embodiments of the present disclosure, as shown in FIG. 4, the first support layer 401 includes a first sub support layer 4011, and the orthographic projection of the first sub support layer 4011 on the base substrate 10 completely covers the orthographic projection of the overlapping area (i.e., the area where the signal transmission electrode 203 is located) on the base substrate 10. In this way, the first sub support layer 4011 can play the role of supporting the metal film bridge 30 and act as a DC bias voltage dielectric layer.

In specific implementation, in the above MEMS device provided by embodiments of the present disclosure, as shown in FIG. 4, the first support layer 401 further includes a second sub support layer 4012 and a third sub support layer 4013, which are arranged at the same layer with the first sub support layer 4011 and are independently arranged with each other. The second sub support layer 4012 and the third sub support layer 4013 are respectively located on both sides of the first sub support layer 4011. In this way, the patterned first support layer 401 can not only prevent the metal film bridge 30 from collapsing, but also reduce the driving voltage of the metal film bridge 30, and can ensure the flexibility of the metal film bridge 30.

In specific implementation, in the above MEMS device provided by embodiments of the present disclosure, as shown in FIG. 4, the second sub support layer 4012 and the third sub support layer 4013 can be symmetrically arranged with respect to the central position of the first sub support layer 4011. In this way, each sub support layer of the patterned first support layer 401 is uniformly distributed, which can further prevent the metal film bridge 30 from collapsing and warping.

Compared with FIG. 3, in the structure shown in FIG. 4, the first support layer 401 is designed with a pattern of multiple sub support layers. It is found through finite element simulation that the structural design in FIG. 4 can improve the supportability of the structure. Under the same external force, compared with the structure shown in FIG. 1 before improvement, the deformation of the metal film bridge 30 is reduced by 50% (i.e. the collapse risk can be reduced by 50% compared with FIG. 1), and the support effect can be adjusted by changing the structural parameters and materials of the first support layer 401. Compared with the structure shown in FIG. 3, in the structure shown in FIG. 4, the deformation of the metal film bridge 30 is reduced by 40% (that is, the collapse risk can be further reduced by 40% compared with FIG. 3), and the support effect can be adjusted by changing the structural parameters and materials of the patterned sub support layers.

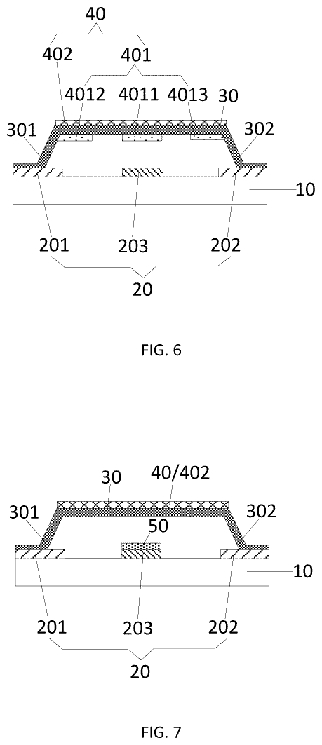

In specific implementation, in the above MEMS device provided by embodiments of the present disclosure, as shown in FIG. 5 and FIG. 6, the support structure 40 further includes a second support layer 402, which is arranged on the side of the metal film bridge 30 facing away from the base substrate 10. In embodiments of the present disclosure, on the basis of the structure of FIG. 3 and FIG. 4, a second support layer 402 is fabricated on the top surface of the metal film bridge 30 facing away from the base substrate 10. On the one hand, the second support layer 402 enhances the support of the metal film bridge 30, and on the other hand, it can also encapsulate the metal film bridge 30 to prevent it from being oxidized.

Specifically, FIG. 5 shows the structure of the second support layer 402 fabricated on the top surface of the metal film bridge 30 facing away from the substrate 10 on the basis of FIG. 3, and FIG. 6 shows the structure of the second support layer 402 fabricated on the top surface of the metal film bridge 30 facing away from the substrate 10 on the basis of FIG. 4. In the structures shown in FIG. 5 and FIG. 6, by fabricating the support layers by on the top and bottom surfaces of the metal film bridge 30 respectively, it is possible to enhance the support effect and to encapsulate the film bridge to prevent oxidation.

The structure shown in FIG. 5 is designed as a stacked structure of first support layer 401/metal film bridge 30/second support layer 402, and it is found through finite element simulation that the design can improve the supportability of the structure, and under the same external force, the deformation of the metal film bridge 30 can be reduced by a further 50% compared with the structure shown in FIG. 3 (that is, the collapse risk can be further reduced by 50% compared with that of FIG. 3). The support effect can be adjusted by changing the structural parameters and materials of the first support layer 401 and the second support layer 402.

In specific implementation, in the above MEMS device provided by embodiments of the present disclosure, as shown in FIG. 7, the support structure 40 includes a second support layer 402, which is arranged on a side of the metal film bridge 30 facing away from the base substrate 10; the MEMS device further includes a dielectric layer 50 on the side of the signal transmission electrode 203 facing away from the base substrate 10. The orthographic projection of the signal transmission electrode 203 on the base substrate 10 and the orthographic projection of the metal film bridge 30 on the base substrate 10 have an overlapping area (that is, the area where the signal transmission electrode 203 is located); and the orthographic projection of the overlapping area on the base substrate 10 is located in the orthographic projection of the dielectric layer 50 on the base substrate 10. In the structure shown in FIG. 7, by fabricating a second support layer 402 on the top surface of the metal film bridge 30, it is possible to enhance the support effect and to encapsulate the film bridge to prevent oxidation.

In specific implementation, in the above MEMS device provided by embodiments of the present disclosure, as shown in FIG. 5 to FIG. 7, the orthographic projection of the second support layer 402 on the base substrate 10 completely covers the orthographic projection of a top surface, facing away from the base substrate 10, of the metal film bridge 30 on the base substrate 10. In this way, on the one hand, each position of the metal film bridge 30 can be uniformly supported, and on the other hand, each position of the metal film bridge 30 can be encapsulated to prevent oxidation.

The structure shown in FIG. 7 designs the MEMS device into a stacked structure of the metal film bridge 30/the second support layer 402. Through simulation, it was found that compared with the embodiments shown in FIG. 3 to FIG. 5, the structural design shown in FIG. 7 can provide the strongest support for the metal film bridge 30 under the support layer with the same material and thickness. Under the same external force, the deformation of the metal film bridge 30 can be reduced by 80% (that is, the collapse risk can be reduced by 80% compared with FIG. 3 to FIG. 5), and the support effect can be adjusted by changing the structural parameters and materials of the second support layer 402.

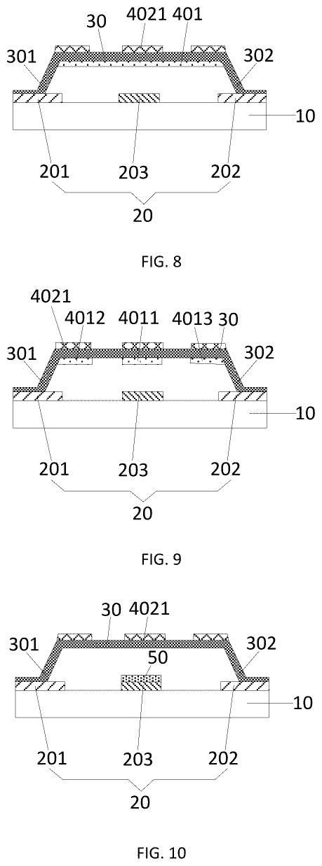

Of course, in specific implementation, as shown in FIGS. 8 to 10, the second support layer 402 can include at least two fourth sub-support layers 4021 (taking three fourth sub-support layers as examples) independently arranged with each other. That is, the second support layer 402 in FIG. 5 to FIG. 7 is patterned, so that the patterned second support layer 402 can prevent the metal film bridge 30 from collapsing while also reducing the driving voltage of the metal film bridge 30.

In specific implementation, in the above-mentioned MEMS devices provided in embodiments of the disclosure, as shown in FIGS. 8 to 10, the at least two fourth sub support layers 4021 are uniformly distributed.

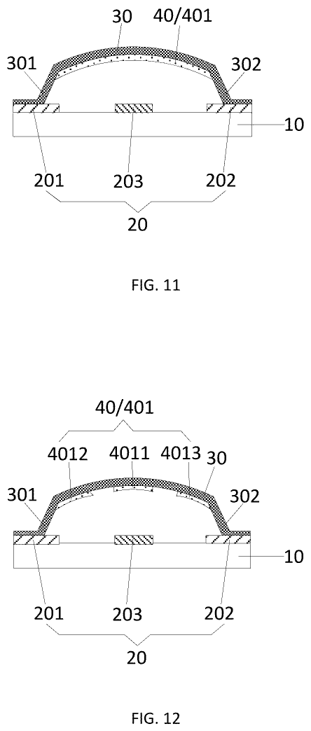

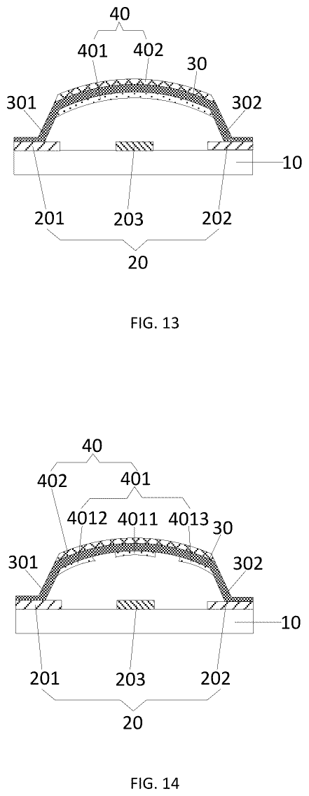

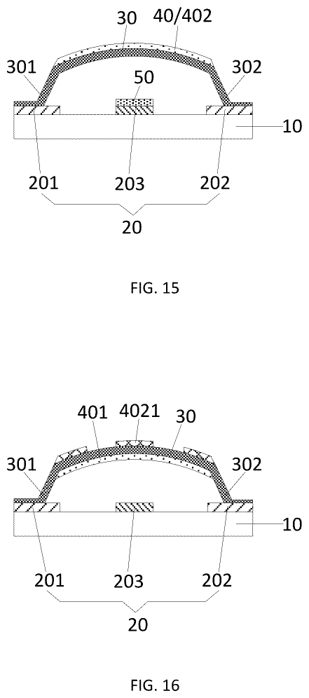

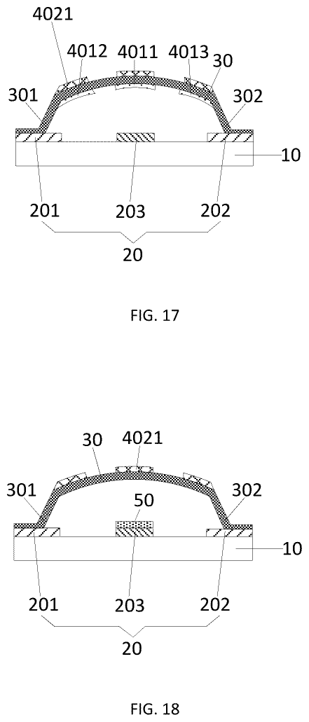

In specific implementation, in the above MEMS device provided by embodiments of the present disclosure, as shown in FIGS. 11 to 18, the shape of the metal film bridge 30 can be an arch protruding to the side away from the base substrate 10. By designing the straight metal film bridge 30 in FIGS. 3 to 10 as an arch structure that protrudes upward, on the one hand, arch structure can increase the distance between the metal film bridge 30 and the signal transmission electrode 203, and on the other hand, it can enhance the downward bending stiffness of the metal film bridge 30, so as to provide stronger support for the metal film bridge 30, and further prevent the collapse and warping of the metal film bridge 30 during the preparation process. The inventors of the present disclosure found through finite element simulation that under the same external force, the deformation of the arched metal film bridge provided in the embodiments of the present disclosure can be reduced by 35% compared with the structure shown in FIG. 1 (that is, the collapse risk can be reduced by 35% compared with FIG. 1). The specific support effect can be adjusted by changing the arch degree of the metal film bridge 30.

In specific implementation, in the above MEMS device provided by embodiments of the present disclosure, as shown in FIGS. 3 to 18, the materials of the metal film bridge 30 can include but are not limited to Au, Ag, Cu or Al, and these metal materials have certain elasticity, which can deform under the action of driving voltage to realize the role of mechanical switch. The materials of the support structure 40 can include but are not limited to SiNx or SiO₂, and the Young's modulus of SiNx and SiO₂ are both greater than the Young's modulus of Au, Ag, Cu and Al, thus providing support for the metal film bridge 30.

In specific implementation, in the above MEMS device provided by embodiments of the present disclosure, as shown in FIG. 3 to FIG. 18, the thickness of the support structure 40 can be 100 nm to 200 nm, such as 100 nm, 150 nm, 200 nm, and so on. If the thickness of the support structure 40 is too small, such as less than 100 nm, it will not serve as a support. If the thickness of the support structure 40 is too large, such as more than 200 nm, the MEMS device requires a larger driving voltage to achieve the switching effect and increase power consumption. Therefore, in the embodiments of the present disclosure, the thickness of the support structure 40 is selected in the range of 100 nm to 200 nm, which can support the metal film bridge 30 without increasing the power consumption of MEMS devices.

Optionally, in the embodiments of the present disclosure, there is no special limitation on the specific types of MEMS devices, which may include, but are not limited to, a phase shifter, a reconfigurable antenna, a switch, or reconfigurable communication devices based on switch structures. Those skilled in the art can also make choices according to the actual situation.

Based on the same inventive concept, embodiments of the present disclosure further provide an electronic device, including the above MEMS device provided by embodiments of the present disclosure. Since the principle of the electronic device to solve the problem is similar to the principle of the aforementioned MEMS device to solve the problem, the implementation of the electronic device can refer to the implementation of the aforementioned MEMS device, and the repetition will not be repeated.

Embodiments of the invention provide a MEMS device and an electronic device, the support structure fixed with the metal film bridge is arranged, since the Young's modulus of the support structure is greater than the Young's modulus of the metal film bridge, the support structure can provide strong support for the metal film bridge and enhance the bending stiffness of the metal film bridge, to prevent the metal film bridge from collapsing or warping and other failure problems during the preparation process, so that the MEMS device can maintain good structure, function and stability.

Although the preferred embodiments of the present disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of the disclosure.

Obviously, those skilled in the art can make various modifications and variations to the present disclosure without departing from the spirit and scope of the present disclosure. Thus, if such modifications and variations of the embodiments of the present disclosure fall within the scope of claims of the present disclosure and their technical equivalents, the present disclosure is intended to include such modifications and variations.

1. An MEMS device, comprising:
a base substrate;
an electrode structure on the base substrate, wherein the electrode structure comprises a first ground electrode, a signal transmission electrode, and a second ground electrode arranged in sequence and spaced on the base substrate;
a metal film bridge spanning above the signal transmission electrode and forming a cavity with the signal transmission electrode, wherein two ends of the metal film bridge are electrically connected with the first ground electrode and the second ground electrode, respectively; and
a support structure, fixedly arranged with the metal film bridge, wherein a Young's modulus of the support structure is greater than a Young's modulus of the metal film bridge.

2. The MEMS device according to claim 1, wherein the support structure comprises a first support layer, the first support layer is arranged on a side of the metal film bridge facing the base substrate;
an orthographic projection of the signal transmission electrode on the base substrate and an orthographic projection of the metal film bridge on the base substrate have an overlapping area; and
an orthographic projection of the first support layer on the base substrate at least completely covers an orthographic projection of the overlapping area on the base substrate.

3. The MEMS device according to claim 2, wherein the orthographic projection of the first support layer on the base substrate completely covers an orthographic projection of a bottom surface of the metal film bridge on the base substrate, wherein the bottom surface of the metal film bridge is a surface of the metal film bridge facing the base substrate.

4. The MEMS device according to claim 2, wherein the first support layer comprises a first sub support layer; and
an orthographic projection of the first sub support layer on the base substrate completely covers the orthographic projection of the overlapping area on the base substrate.

5. The MEMS device according to claim 4, wherein the first support layer further comprises a second sub support layer and a third sub support layer;
wherein the first sub support layer, the second sub support layer and the third sub support layer are on a same layer and arranged independently with each other, and the second sub support layer and the third sub support layer are located on both sides of the first sub support layer, respectively.

6. The MEMS device according to claim 5, wherein the second sub support layer and the third sub support layer are symmetrically arranged with respect to a central position of the first sub support layer.

7. The MEMS device according to claim 2, wherein the support structure further comprises a second support layer; and
the second support layer is arranged on a side of the metal film bridge facing away from the base substrate.

8. The MEMS device according to claim 1, wherein the support structure comprises a second support layer; and the second support layer is arranged on a side of the metal film bridge facing away from the base substrate;
the MEMS device further comprises a dielectric layer on a side of the signal transmission electrode facing away from the base substrate;
an orthographic projection of the signal transmission electrode on the base substrate and an orthographic projection of the metal film bridge on the base substrate have an overlapping area; and
an orthographic projection of the overlapping area on the base substrate is located within an orthographic projection of the dielectric layer on the base substrate.

9. The MEMS device according to claim 7, wherein an orthographic projection of the second support layer on the base substrate completely covers an orthographic projection of a top surface of the metal film bridge on the base substrate, wherein the top surface of the metal film bridge is a surface of the metal film bridge facing away from the base substrate.

10. The MEMS device according to claim 7, wherein the second support layer comprises at least two fourth sub support layers independently arranged with each other.

11. The MEMS device according to claim 10, wherein the at least two fourth sub support layers are uniformly distributed.

12. The MEMS device according to claim 1, wherein a shape of the metal film bridge is an arch protruding toward a side away from the base substrate.

13. The MEMS device according to claim 1, wherein a material of the metal film bridge comprises Au, Ag, Cu or Al; and a material of the support structure comprises SiNx or SiO₂.

14. The MEMS device according to claim 1, wherein a thickness of the support structure ranges from 100 nm to 200 nm.

15. An electronic device, comprising the MEMS device according to claim 1.

16. The MEMS device according to claim 8, wherein an orthographic projection of the second support layer on the base substrate completely covers an orthographic projection of a top surface of the metal film bridge on the base substrate, wherein the top surface of the metal film bridge is a surface of the metal film bridge facing away from the base substrate.

17. The MEMS device according to claim 8, wherein the second support layer comprises at least two fourth sub support layers independently arranged with each other.
